(19) United States
(12) Patent Application Publication
(10) Pub. No.: US 2023/0410573 A1
(43) Pub. Date: Dec. 21, 2023

(54) VEHICULAR CONTROL SYSTEM WITH AUTOMATIC SUBSYSTEM SELECTION

(71) Applicant: Magna Electronics Inc., Auburn Hills, MI (US)

(72) Inventor: Mohamed Babaali, Shrewsbury, MA (US)

(21) Appl. No.: 18/337,511

(22) Filed: Jun. 20, 2023

Related U.S. Application Data
(60) Provisional application No. 63/366,657, filed on Jun. 20, 2022.

(51) Int. Cl. G07C 5/08

(52) U.S. Cl. CPC G07C 5/0808

(57) ABSTRACT

A method for testing a vehicular control system includes receiving, at a simulator, data including a plurality of tasks and a plurality of channels, where the tasks communicate via the channels. The method includes receiving, at the simulator and from a user device, a system under test (SUT) selection selecting one of the plurality of tasks for testing. The method includes determining, using the graph and the SUT selection, an inverse reachability set of tasks from the plurality of tasks. The inverse reachability set of tasks includes a subset of the plurality of tasks to provide the SUT selection live data during simulation. The inverse reachability set of tasks does not include at least one task from the plurality of tasks. The method also includes simulating, by the simulator, only the tasks of the inverse reachability set of tasks to test the selected one of the plurality of tasks.

### CROSS REFERENCE TO RELATED APPLICATION

The present application claims the filing benefits of U.S. provisional application Ser. No. 63/366,657, filed Jun. 20, 2022, which is hereby incorporated herein by reference in its entirety.

### FIELD OF THE INVENTION

The present invention relates generally to a vehicular control system or driving assist system for a vehicle and, more particularly, to testing of a vehicular control system or driving assist system.

### BACKGROUND OF THE INVENTION

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties.

### SUMMARY OF THE INVENTION

A method for testing a vehicular control system includes receiving, at a simulator, data including a plurality of tasks and a plurality of channels. Respective tasks of the plurality of tasks communicate via respective channels of the plurality of channels. The method includes receiving, at the simulator, and from a user device, a system under test (SUT) selection selecting one of the plurality of tasks for testing. The method includes determining, using the data and the SUT selection, an inverse reachability set of tasks from the plurality of tasks. The inverse reachability set of tasks includes a subset of the plurality of tasks to provide the SUT selection live data during simulation. The inverse reachability set of tasks does not include at least one task from the plurality of tasks. The method includes simulating, by the simulator, only the tasks of the inverse reachability set of tasks to test the SUT selection.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system that incorporates cameras;

FIG. 2 is a block diagram of two software modules communicating via a channel;

FIG. 3 is a block diagram of three modules communicating via three channels;

FIG. 4 is a block diagram of the modules and channels of FIG. 3 where one of the channels is available for playback;

FIG. 5 is a block diagram of four modules communicating via four channels;

FIG. 6 is a block diagram of three modules communicating via three channels where each channel is available for playback;

FIG. 7 is a block diagram of four modules communicating via four channels where each channel is available for playback;

FIG. 8 is a block diagram of three modules and three channels for message freshness;

FIG. 9 is a block diagram of a module that requires input from two other modules for proper operations;

FIG. 10 if a block diagram of the module of FIG. 9 where two of the modules are ideal modules;

FIG. 11 is a block diagram of three modules communicating via three channels where one of the modules has a defect;

FIG. 12 is a block diagram of the three modules of FIG. 11 where two of the modules are combined into a single module;

FIG. 13 is a block diagram combining the modules of FIG. 11 and FIG. 12;

FIG. 14 is a schematic view of a basic graph;

FIG. 15 is a schematic view of a compressed graph;

FIG. 16 is a schematic view of an activation graph;

FIG. 17 is a schematic view of an activation graph with only a planner active;

FIG. 18 is a schematic view of an activation graph with a live planner;

FIG. 19 is a schematic view of an activation graph with a planner and a controller active;

FIG. 20 is a schematic view of the activation graph of FIG. 19 with the controller, vehicle, and planner active;

FIG. 21 is a schematic view of transducers;

FIG. 22 is a block diagram of simulator components;

FIG. 23 is a graph of components of an estimator simulator;

FIG. 24 is a graph with an idealized estimator simulator;

FIG. 25 is the graph of FIG. 24 with an interpolator added;

FIG. 26 is the graph of FIG. 25 with additional modules active;

FIG. 27 is a block diagram of parallel tasks; and

FIG. 28 is a block diagram for ambiguity resolution and task/channel selection.

### DESCRIPTION OF THE PREFERRED EMBODIMENTS

A vehicle vision system and/or driver or driving assist system and/or object detection system and/or alert system operates to capture sensor data (e.g., images) exterior of the vehicle and may process the captured sensor data to, for example, display images and to detect objects at or near the vehicle and in the predicted path of the vehicle, such as to assist a driver of the vehicle in maneuvering the vehicle in a rearward direction. The vision system may include a data processor or processing system that is operable to receive sensor data from one or more sensors and provide an output to a display device for displaying images representative of the captured sensor data.

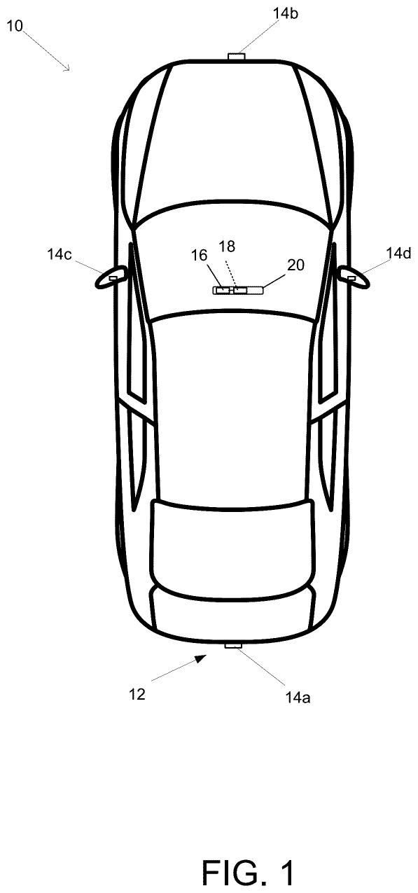

Referring now to the drawings and the illustrative embodiments depicted therein, a vehicle 10 includes an imaging system or control system 12 that includes at least one exterior viewing sensor, such as a rearward viewing imaging sensor or camera 14a (and the system may optionally include multiple exterior viewing imaging sensors or cameras, such as a forward viewing camera 14b at the front (or at the windshield) of the vehicle, and a sideward/rearward viewing camera 14c, 14d at respective sides of the vehicle), which captures images exterior of the vehicle, with the camera having a lens for focusing images at or onto an imaging array or imaging plane or imager of the camera (FIG. 1). Optionally, a forward viewing camera may be disposed at the windshield of the vehicle and view through the windshield and forward of the vehicle, such as for a machine vision system (such as for traffic sign recognition, headlamp control, pedestrian detection, collision avoidance, lane marker detection and/or the like). The control system 12 includes a control or electronic control unit (ECU) 18 having electronic circuitry and associated software, with the electronic circuitry including a data processor or image processor that is operable to process image data captured by the sensors (e.g., cameras, radar, lidar, etc.) whereby the ECU may detect or determine presence of objects or the like and/or the system provide displayed images at a display device 16 for viewing by the driver of the vehicle (although shown in FIG. 1 as being part of or incorporated in or at an interior rearview mirror assembly 20 of the vehicle, the control and/or the display device may be disposed elsewhere at or in the vehicle). The data transfer or signal communication from the camera to the ECU may comprise any suitable data or communication link, such as a vehicle network bus or the like of the equipped vehicle.

In many robotics applications, including autonomous vehicles (AVs), embedded software (such as software that executes the driver assist system or control system of FIG. 1, e.g., an object detection system, a lateral motion control system, a longitudinal motion control system, etc.) is broken down into small modules that communicate with each other. For example, modules may include a motion planner, a controller, a neural network, etc. Modules may run as different processes or threads on the same or different processors or other computing or data processing hardware. The data being exchanged may be an image from a camera, a short-term motion plan, an actuator signal/sensor data, or the like. Communication may follow a publisher/subscriber model, which allows modules to operate concurrently without accounting for synchronization and locking while waiting for data. In such a model, a piece of data (referred to herein as a message) that is to be communicated from a first module to a second module is first sent to a queue that gathers all such messages. The second module may then then query the queue for the most recent messages whenever the second module sees fit. This is commonly referred to as asynchronous communication. Different queues for different message types are typically distinguished by their channel names.

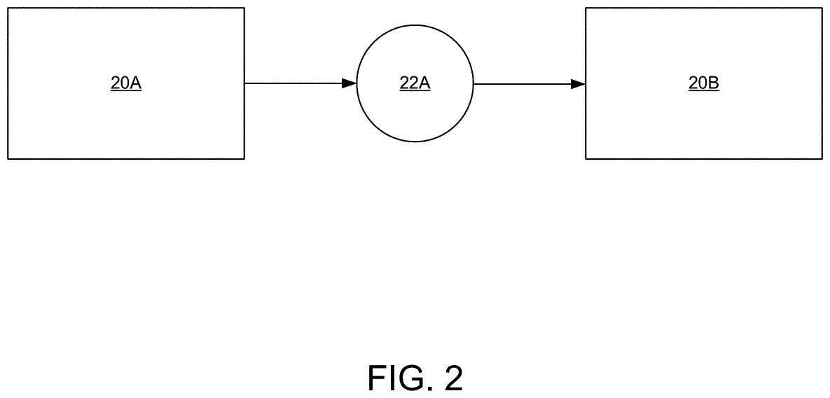

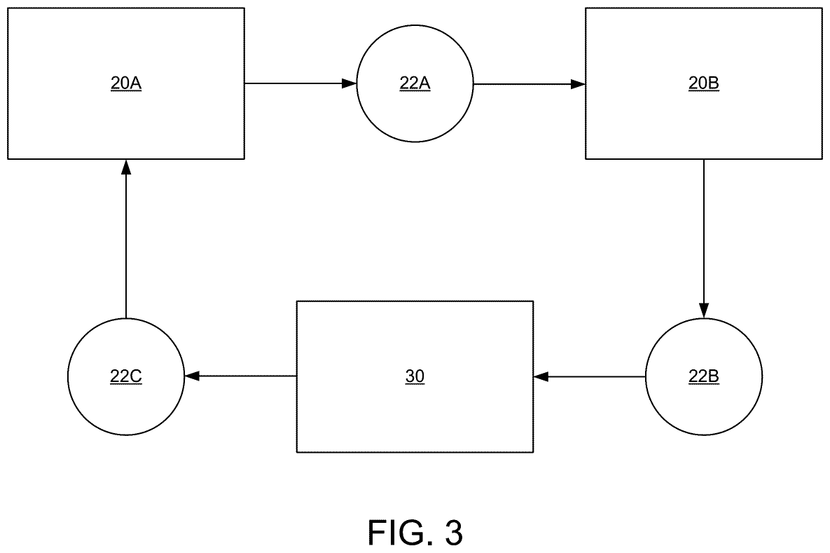

Referring now to FIG. 2, a channel 22A establishes communication between two modules 20A, 20B. FIG. 2 thus represents a system with two blocks or modules 20A, 20B such that the module 20A sends data over channel 22A to the module 20B. In addition to embedded modules, many AV development teams develop simulation modules that are not intended to be deployed to the embedded system. These modules instead run alongside embedded modules on development computing devices in order to test the embedded software. The simulation modules simulate the environment that the embedded software will encounter in the real world (i.e., during actual use on the vehicle). For example, a simulation module may simulate the dynamics of a vehicle equipped with the system under test to ensure that actuator signals produced by a controller of the system under test steer the vehicle satisfactorily. FIG. 3 illustrates a simulation module 30 added to the modules 20A, 20B of FIG. 1, along with channels 22B, 22C for communication between the modules.

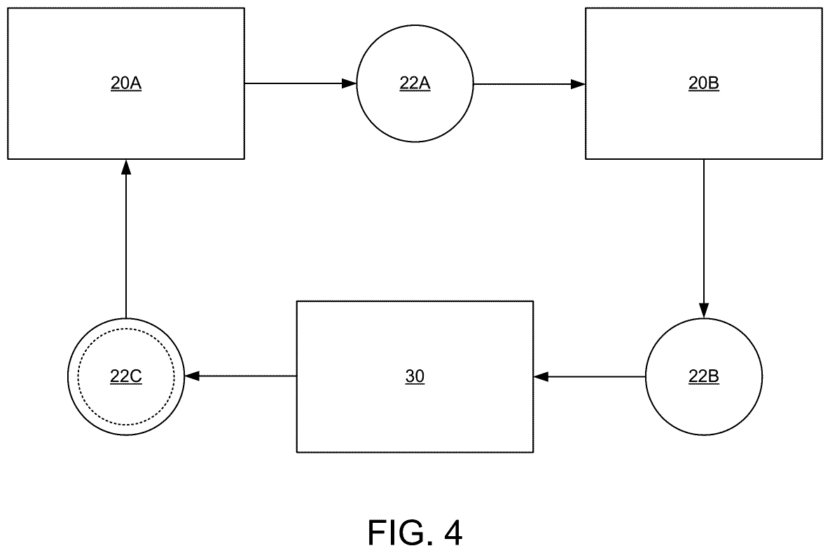

In some scenarios, logs of all the messages that certain channels receive or transmit during a previous experiment, either on the vehicle or in simulation, are recorded or kept or stored. It is often useful to replay these logs for testing or validation purposes. As shown in FIG. 4, a channel 22C is available for playback. In this example, the channel 22C will replay messages received from the simulation module 30 to the module 20A. For example, a developer of the module 20A desires to test the module 20A using, for example, a tool that allows specification of which modules to launch, along with some scenario parameters, such as a route identifier and starting point (e.g., using a JavaScript Object Notation (JSON) test file.

Continuing this example, when only the module 20A is executed, then the channel 22C never receives messages because the module 30 is not running. This is generally undesirable as the module 20A may require some messages be made available at a certain frequency in order to operate normally. A module is “live” when all the channels that feed the module are being appropriately published to. In FIG. 4, the module is live if and only if the module 30 is also running at the same time. If the example is adjusted to execute both the module 20A and the module 30, then while the module 20A has a publisher to its inputs executing (i.e., the module 30), the module 30 does not have a publisher, as the module 30 requires the module 20B to publish to the channel 22B. Therefore, the module 30 may not execute properly and thus may not publish appropriate data to the channel 22C. Thus, in this example, in order to achieve liveness, each of the modules 20A, 20B, 30 must be executed.

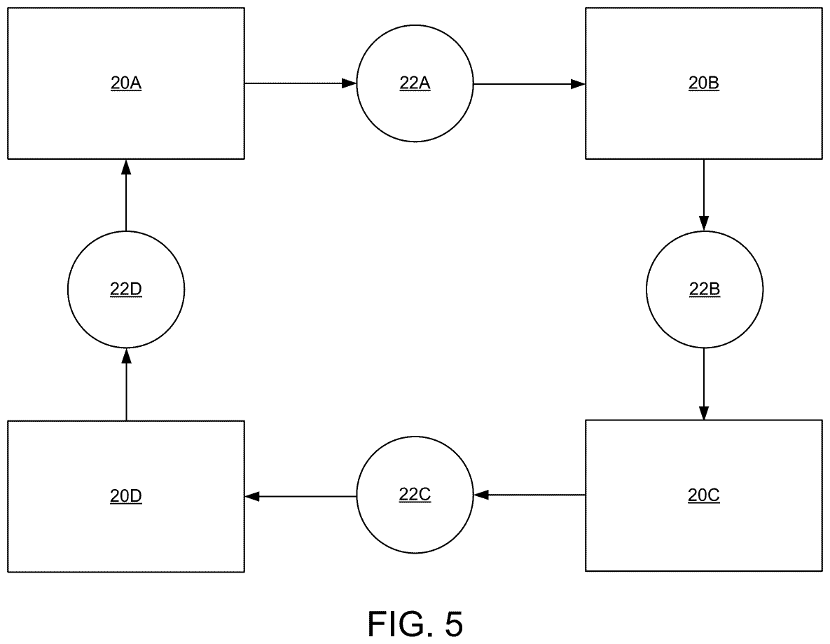

That is, in the example of FIG. 4, when the module 20A is the system under test (SUT), a live test requires a set comprising all three modules 20A, 20B, 30. This may be referred to as a liveness preserving set (LPS). In some implementations, an automatic subsystem selection system automatically determines the LPS in response to a specified SUT. Automatic LPS determination is advantageous for both development and testing of systems. For example, FIG. 5 includes four modules 20A-D and four channels 22A-D. Here, a test file for preserving liveness would include executing each of the modules 22A-D. However, manually specifying the LPS for an SUT test or simulation results in a significant software maintenance problem. For example, at an organization that develops an AV system comprising a significant number of modules and maintains thousands of test files that each specify an LPS, it is easy to conceive of a situation in which adding a single new module to the system results in having to update hundreds or thousands of test files in order to preserve liveness. On the other hand, using the implementations described herein, a user only specifying the SUT (and the LPS determined automatically) may have to update zero test files to reflect changes to liveness, thus greatly decreasing maintenance efforts and the likelihood of stale or out of date files affecting tests.

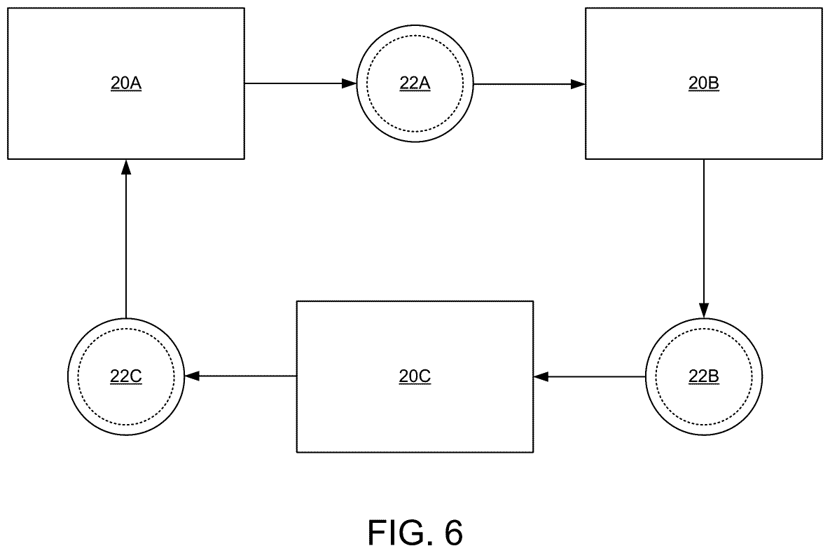

As discussed previously, playback is the ability to play back all the messages that went through a channel in a reference simulation or run in a subsequent simulation. It is common for developers, when testing a SUT, to simulate the SUT with playback. Referring now to FIG. 6, in this example, channels 22A-C are available for playback and the module 20A is the SUT. In this scenario, the tester typically must determine what modules are necessary to execute and which channels to play back. In this example, it may be possible to execute just the SUT (e.g., the module 20A) as long as channel 22C is played back in order to keep the module 20A alive. In order to avoid collisions, the tester may want to avoid playback from the channel 22A. Thus, in this example, the test may generate a test file that designates the module 20A as the SUT and the channel 22C for playback. Implementations herein include automatically determining the minimum set of channels to play back when given an SUT. For example, the tester may generate a test file that only specifies the SUT (and not the channels for playback) and the system automatically determines the minimum set of channels for playback to test the SUT with liveness.

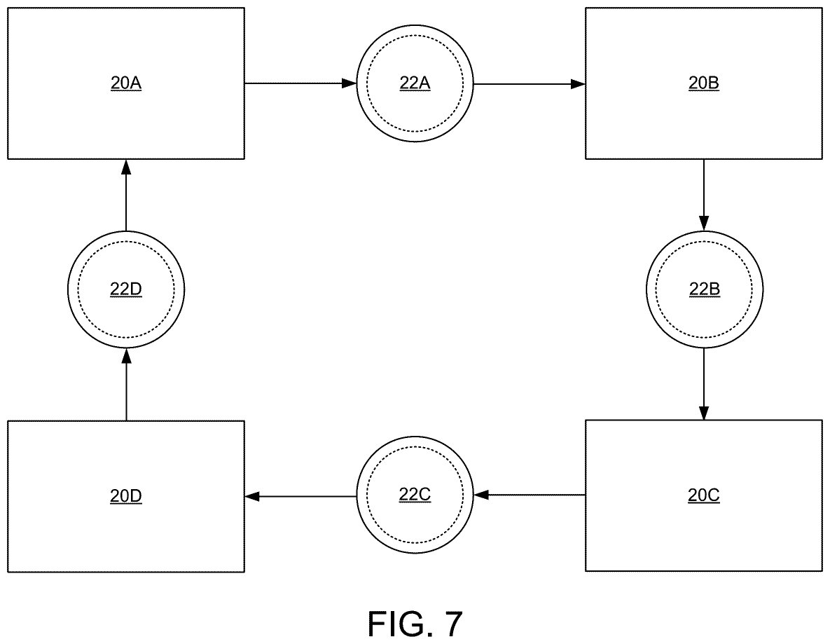

Such a system may have a tremendous effect on maintainability. For example, referring to FIG. 7, an exemplary system includes four modules 20A-D and four channels 22A-D. In the example of FIG. 7, the SUT is the module 20A. If the example of FIG. 6 were modified to reflect the example of FIG. 7, conventional test files would need updating to instead specify channel 22D for playback (FIG. 7) instead of channel 22C for playback (FIG. 6). That is, this example shows that even a small change in the system (e.g., adding or removing a single module or adding or removing a single channel) causes a large number of playback test files to be modified. This makes maintenance not only a significant time investment, but also prone to errors.

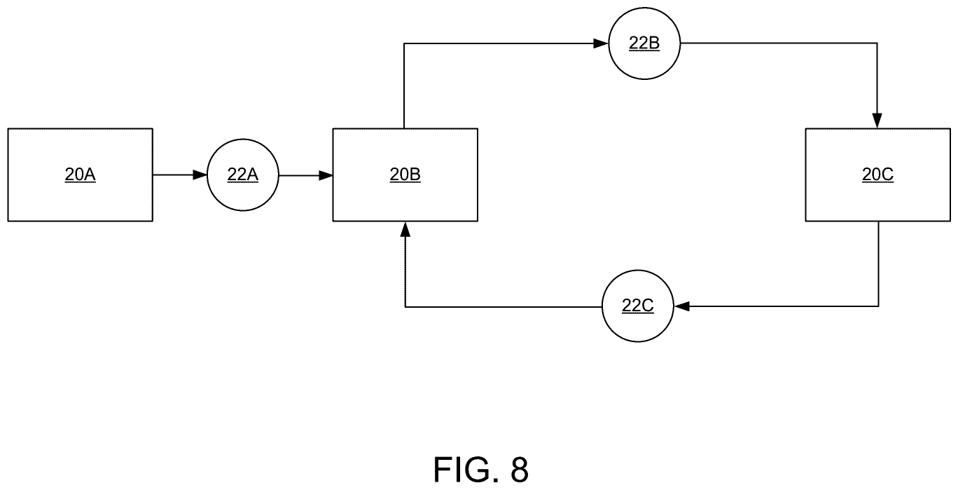

Referring now to FIG. 8, another exemplary system includes four modules 20A-D and three channels 22A-C. Here, the SUT is the module 20B. In this example, for proper simulation, the channel 22A and the channel 22C must each enable play back, as both of the channels provide inputs to the SUT. However, the module 20B publishes messages to the channel 22B that are used by the module 20C to publish “fresh” messages to the channel 22C (fresh as opposed to the stale messages from the reference run). In this scenario, it may be beneficial to execute the module 20C so that the module 20B may consume fresh messages. In some implementations, the automatic subsystem selection system adds modules to run alongside the SUT in order to guarantee the freshness of all the messages that the SUT receives. For example, the tester generates test files with a freshness flag (e.g., a Boolean value setting freshness to true or false). Based on the flag, the automatic subsystem selection system determines whether to incorporate additional modules for freshness. This greatly improves maintainability for software repositories.

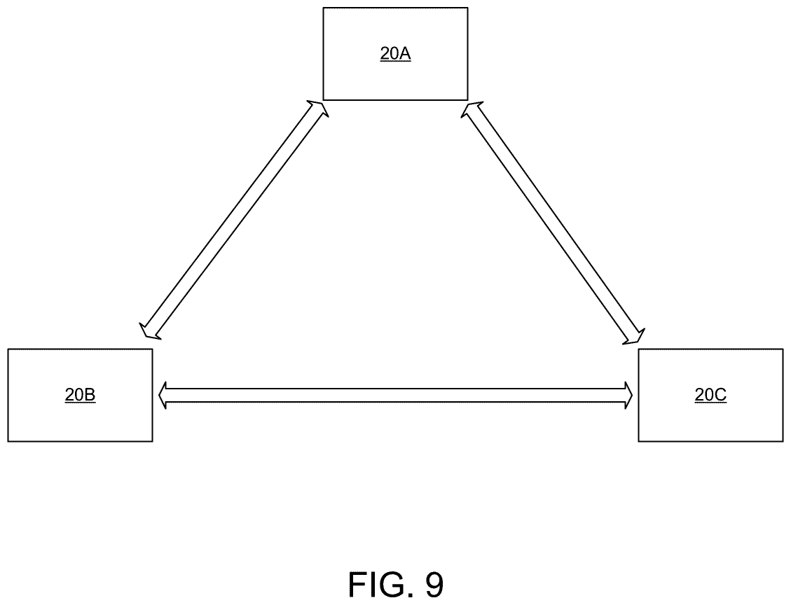

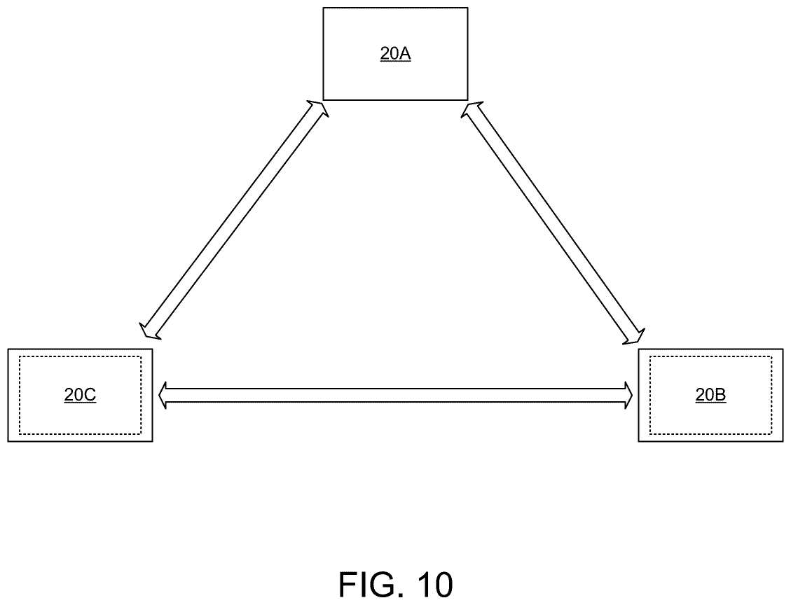

Referring now to FIG. 9, software engineers typically work on modules where a module references a small unit of code (relative to the entire codebase). For example, an engineer is responsible for a first module. It is very common for the first module to only be exercisable (i.e., testable) in the presence of other modules (e.g., a second module and a third module). That is, the engineer must execute the second and third modules at the same time as the first module in order for the first module to execute properly. For example, the first module may call the other modules directly or may need some data that the other modules produce. This example is illustrated in FIG. 9, with the first module 20A, the second module 20B, and the third module 20C. When a bug (i.e., an error or fault in the design or development of the module) is detected in the first module 20A, the first module 20A must be debugged. A crucial aspect of the debugging process is the delineation of the bug search space that happens throughout the process, but especially at the beginning. The bug search space defines the portions of the codebase where the bug may be located. For example, the bug search space may be defined as just the first module 20A or as each of the three modules 20A-C. The answer to the question is crucial, because the answer can drastically change the scope (i.e., the amount of time and/or engineers required) of the debugging process. Software architects and engineers conventionally solve this problem by assuming that every other module is without fault. For example, here, the developer of the first module 20A may assume that the second module and the third module 20C are bug-free. This is one of the most important attributes of a well-executed modular codebase. One way to achieve such a module codebase is to ensure that every module is fully tested by an exhaustive unit test suite. For example, in FIG. 10, the second module 20B and the third module 20C are designated as “bug-free” modules.

Autonomous vehicle software development experiences the same or similar problems with software faults. For example, the faults or bugs may include the car failing to stop at a stop sign or colliding with an obstacle. For such bugs, the search space is conventionally most or all of the AV software stack, because it is very difficult to eliminate any module from the search space. One potential way to explain this is that each module operates with a limited amount of data and is not actually guaranteed to always provide the correct answer.

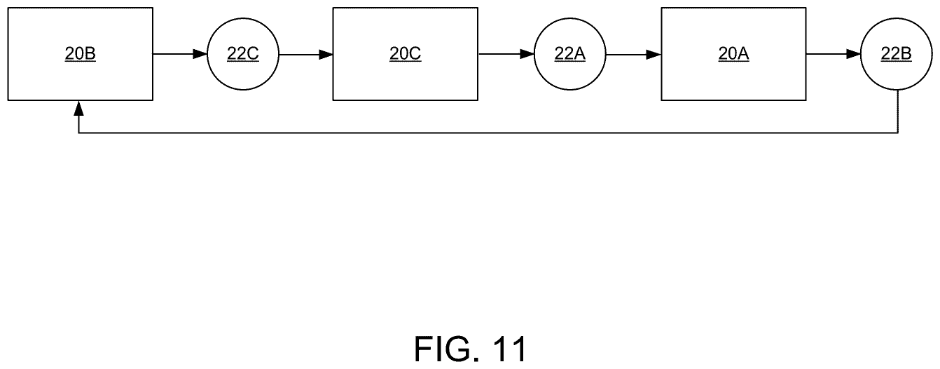

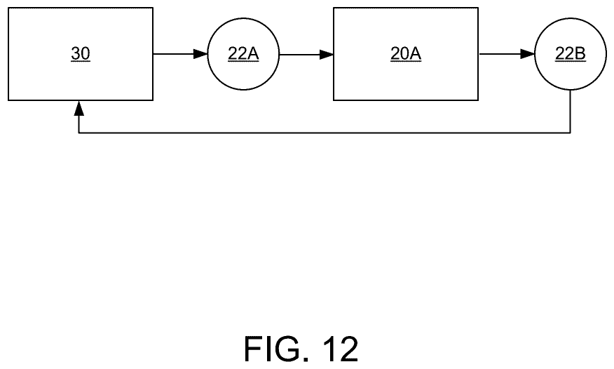

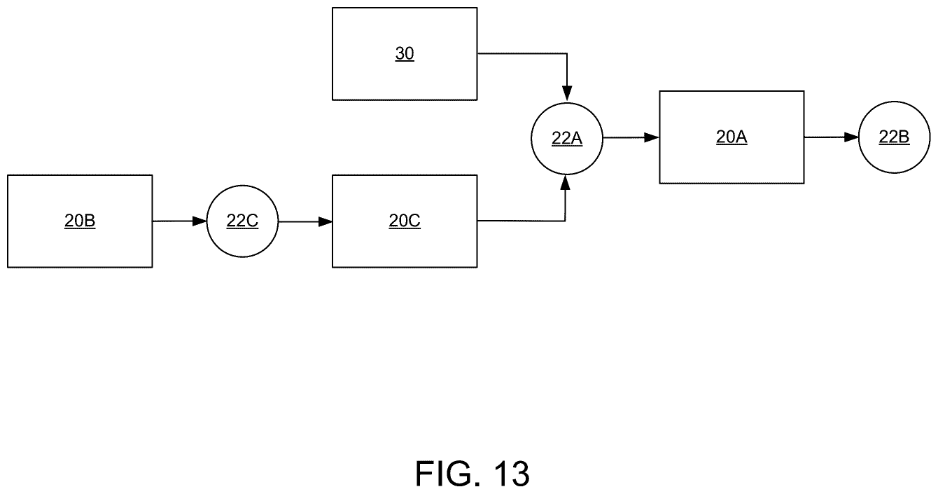

Referring now to FIG. 11, an exemplary AV system includes three modules and three channels 22A-C. When debugging this system, an issue may occur in any of the modules 20A-C. In order to reduce the search space for debugging, it would be advantageous if the modules 20B, 20C were ideal (i.e., bug-free). However, this generally cannot be guaranteed. However, the behaviors of these modules may be simulated in an ideal way. For example, FIG. 12 illustrates an exemplary system where the modules 20B, of FIG. 11 have been replaced with a single simulation module 30. The simulation model 30 generates outputs that look “ideal” to the module 20A. This allows a developer of the module 20A to reduce the search space to just the module 20A. However, sometimes the capability of executing the actual modules 20B, 20C must be maintained (e.g., to test those modules). This results in the exemplary system of FIG. 13.

As shown in FIG. 13, there are two modules 20C, 30 publishing to the same channel 22A. Generally, only one module will execute at a time to avoid collision in messages. For example, the test file always selects only the simulation model 30 or the actual module 20C for execution. For instance, when the SUT is the module 20A, the test file may ensure liveness with idealization (i.e., execute the modules 20A, 30) or ensure liveness without idealization (i.e., execute the modules 20A-C). For example, a test file may include a “flavor” flag that indicates whether the test should be ideal or not ideal. The automatic subsystem selection system, based on the flavor flag, may automatically determine which modules to execute in response (i.e., whether to execute idealized simulations of modules or the actual modules). That is, the automatic subsystem selection system may automatically determine the set of modules to execute based on whether idealization is desired by the test or not. For example, every module may be marked as an idealized module or a non-idealized module which the automatic subsystem selection system may favor/disfavor depending on the flags set in the test file.

Thus, as described in more detail below, the automatic subsystem selection system may parse a number of flags provided in a test file or other input to determine which modules should be executed when running the test. The test file may indicate the SUT and, for example, modules that must be excluded, a flavor flag for indicating whether modules should be ideal/not ideal, a freshness flag indicating whether freshness is required for playback, and/or a playback flag that lists the channels that are available for playback. This may be a binary flag indicating that all or none of the channels are available for playback or may indicate which channels are available independently. The automatic subsystem selection system may parse the test file, including the SUT and flags and, for example, a block diagram of the test modules, and determine the smallest number of modules required to properly execute the test and satisfy the constraints. By minimizing the set of modules, the automatic subsystem selection system reduces resources and time necessary for testing while drastically improving test file maintainability. The automatic subsystem selection system may execute each time a test is executed (i.e., the system may select the modules required in real-time). Alternatively, the automatic subsystem selection may be executed periodically to update test files (e.g., once an hour, once a day, once a week, etc.).

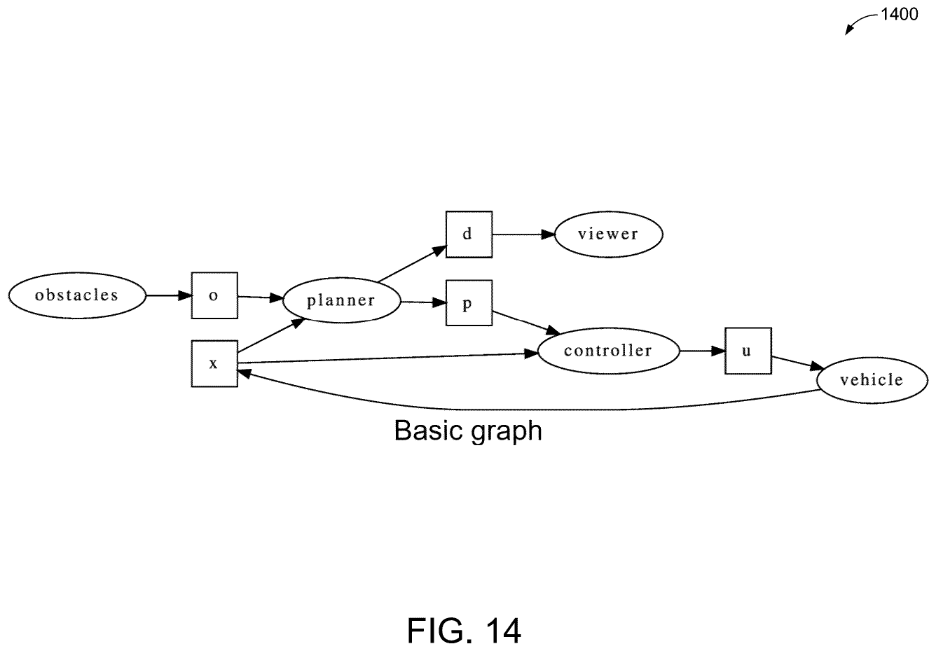

Referring now to FIG. 14, a basic directed graph 1400 or diagram or flow chart includes ovals that represent tasks and squares that represent channels. Here, a directed edge from a task to a channel indicates that the task publishes to that channel and a directed edge from a channel to a task indicates that the task subscribes to that channel. This representation guarantees that each of a task's inputs come from a different channel. Using this guarantee and definition, liveness becomes a backward walk through the graph's connected components.

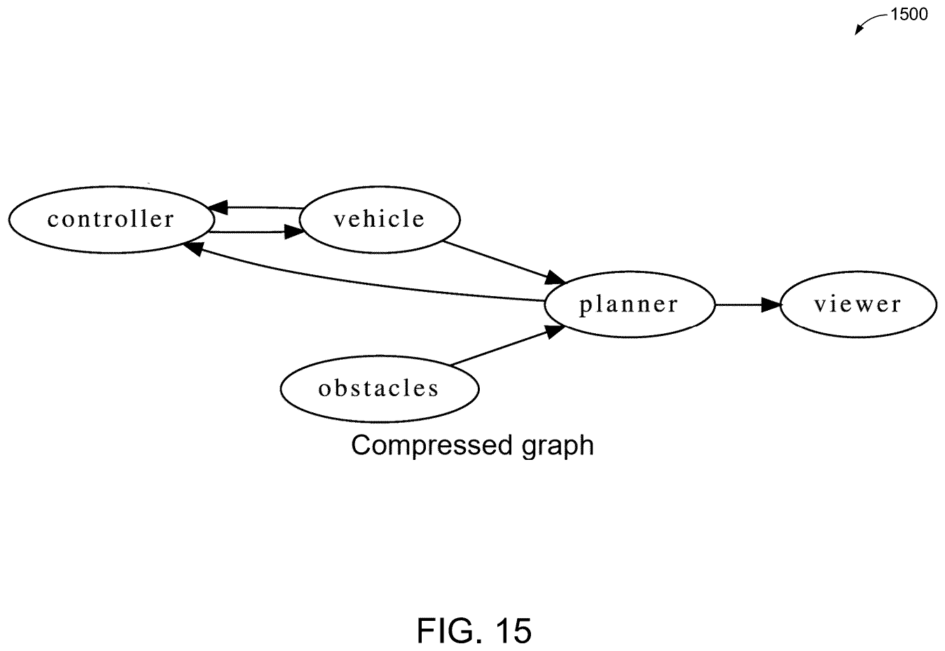

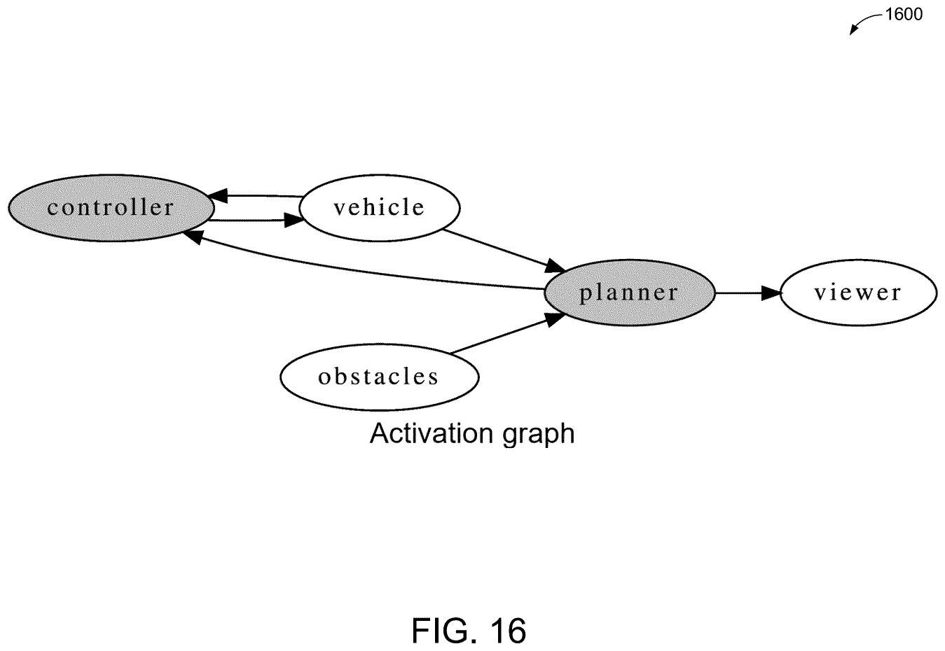

Referring now to FIG. 15, the basic graph 1400 (FIG. 14) may be compressed into a compressed graph 1500 when it is assumed that no two active tasks publish to the same channel. A subset of tasks is defined as collision-free when no two tasks publish to the same channel. Whenever a set is collision-free, the graph may omit all channel nodes and instead connect two tasks directly whenever the destination subscribes to a channel that the source publishes to (i.e., absorbing each channel node into its publisher). This results in the compressed graph 1500. An activation graph 1600 (FIG. 16) highlights the tasks that have actually been selected to run. In this example, only the planner and the controller have been selected to be executed. The graphs (e.g., the graphs 1400, 1500, 1600) may be generated from module or task configuration files (e.g., JSON files) that list the channels that the modules subscribe or publish to. Alternatively, the graphs may be generated from logging channel subscriptions made by modules during simulation or during production (i.e., on the embedded system). A graph builder may transform the channel subscriptions into the graphs.

Unit testing, where the user generates any inputs for the unit from scratch, while powerful, may be difficult or time-consuming for many tasks. Instead, simulating a portion of the system may reduce or eliminate input generation by instead using a closed loop or log playback. However, this requires determining what modules are required to execute alongside the SUT. At one end of the spectrum, running the SUT by itself (without any playback) is generally not a good idea because the SUT may not get any inputs to process (and thus may not operate correctly or completely). At the other end of the spectrum, there are likely modules that are not required and simulating the unrequired modules uses more resources than is necessary and/or there may be colliding tasks. Thus, in general, executing all available tasks or modules is not ideal. Instead of relying on developers to fully select what tasks to run in conjunction with the SUT, which has proven tedious, error-prone, and hard to maintain, the automatic subsystem selection system automates this task.

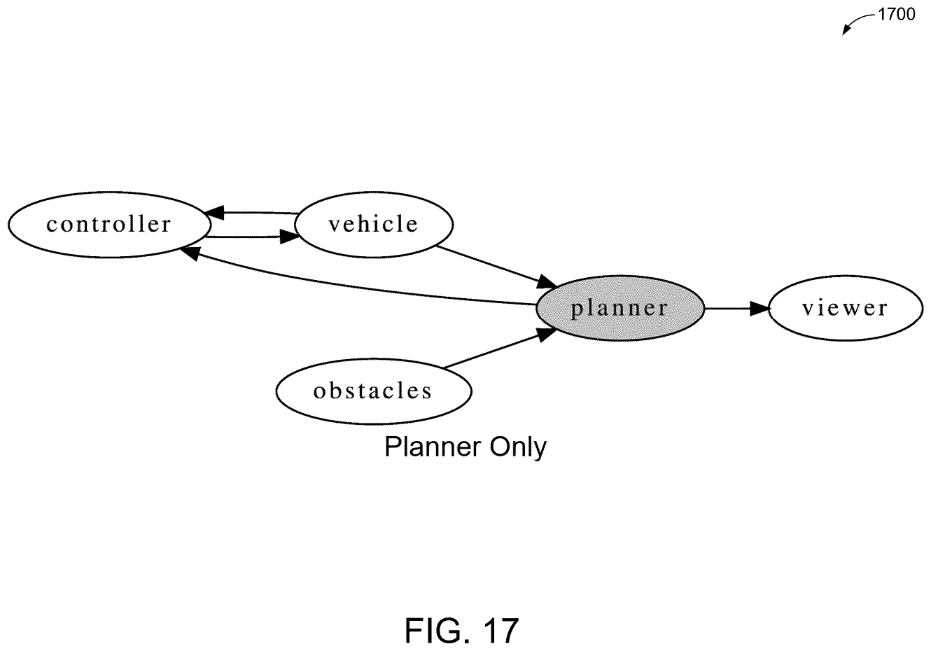

As previously discussed, a subset of tasks is defined to be live if all tasks receive all their inputs at the expected frequencies (e.g., on the vehicle or otherwise). For example, as illustrated in FIG. 17, the user desires to execute a planner of the graph 1700. When the planner is executed by itself, then the planner may “starve” because it does not receive necessary inputs from the vehicle, controller, and obstacles modules. Thus, it is necessary to determine the modules that must be run to preserve liveness. However, minimizing this set is advantageous to reduce resource consumption. Assuming that, when a task that subscribes as publisher to a channel is running, the channel is being published to at the correct frequency (relative to what the task desires), liveness may be characterized as requiring every task input to be connected. To determine the minimal live set, the system may recursively search for each task that must execute before the specified task (i.e., the SUT). Thus, when using a strongly connected graph (i.e., each vertex is reachable from each other vertex), the minimal live set is the strongly connected component containing the SUT, along with all precursor components in the graph's contraction (obtained by contracting all strongly connected components into vertices), which is a directed acyclic graph (DAG). In some examples, the automatic subsystem selection system, to determine the minimal set, determines an inverse reachability set of all tasks in the SUT. For example, the automatic subsystem selection system determines a transpose graph of the original graph and/or performs a single depth-first search (DFS) to determine each of the vertices that are reachable from every node in the SUT. This results in a set of nodes required to execute for the SUT.

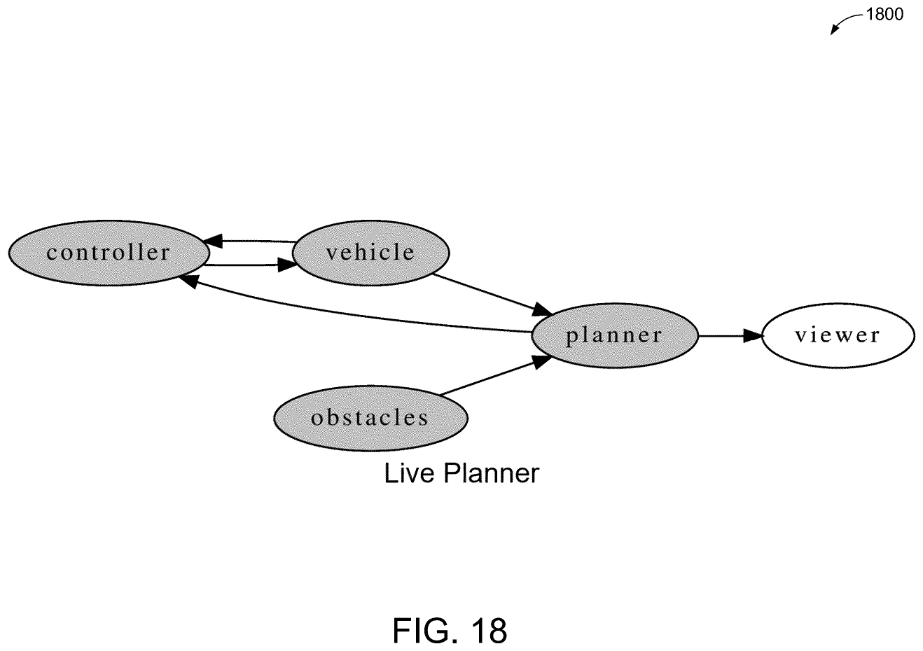

In the example of FIG. 17, this results in executing everything except the viewer module (FIG. 18). Note that, in the graph 1800, there are three strongly connected components. That is, the controller, the planner, and the vehicle make up a strongly connected component, the obstacles module makes up another strongly connected component, and the viewer module makes up yet another strongly connected component. The automatic subsystem selection system executes in linear time when determining the minimal set of tasks or modules.

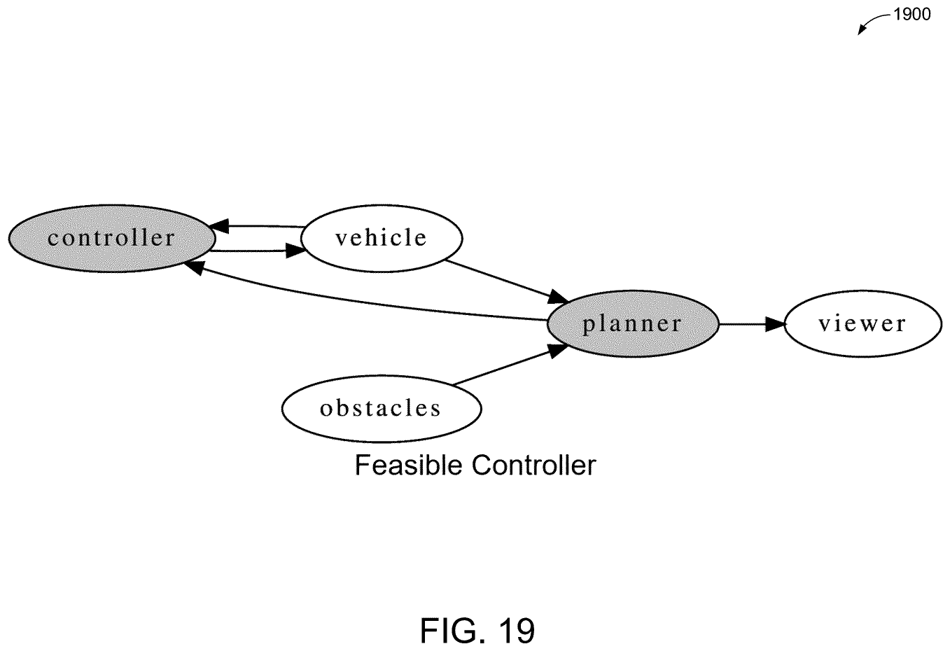

In some implementations, the automatic subsystem selection system selects and/or executes a subset of tasks from a set of tasks while playing back messages from a dataset. This may include the assumption that the dataset contains data from all channels and the compressed graph format may eliminate collision concerns. The automatic subsystem selection system may determine a minimal collision-free set of tasks based on executing a given set of tasks and playing back all direct input channels and all direct output channels. For example, a graph 1900 (FIG. 19) includes a controller module, a vehicle module, an obstacles module, a planner module, and a viewer module. In this example, the SUT includes the planner module and the controller module (i.e., both modules together).

As shown in FIG. 19, a minimum collision-free set may include only the controller module and the planner module. However, this may raise some issues. For example, the planner may receive the played back state because the vehicle is not being simulated. But the controller, which is also executing, may publish a message that should modify the state. That is, the controller module may publish a message to the vehicle module that, if the vehicle module were actually executing, would cause the vehicle module to output a message that is different from the playback message. This may be defined as a concept of consistency. That is, in log playback, a subset of tasks is consistent if no task is being fed a signal that is not fresh when there is a potential fresh signal available, pending extra task activations. Fresh signals may be defined recursively as, given an active set of tasks, when a task is executing, then all of the outputs of the task are fresh and when a task is not executing and any of the inputs of the task are fresh, then each of the outputs of the task would be fresh if the task was activated. Given this definition, the automatic subsystem selection system determines a minimal collision-free and consistent set of tasks. Given the strongly connected component decomposition, the automatic subsystem selection system may determine the minimum collision-free, consistent set of tasks based on all strongly connected components containing any of the tasks given and all component paths between those strongly connected components (in linear time).

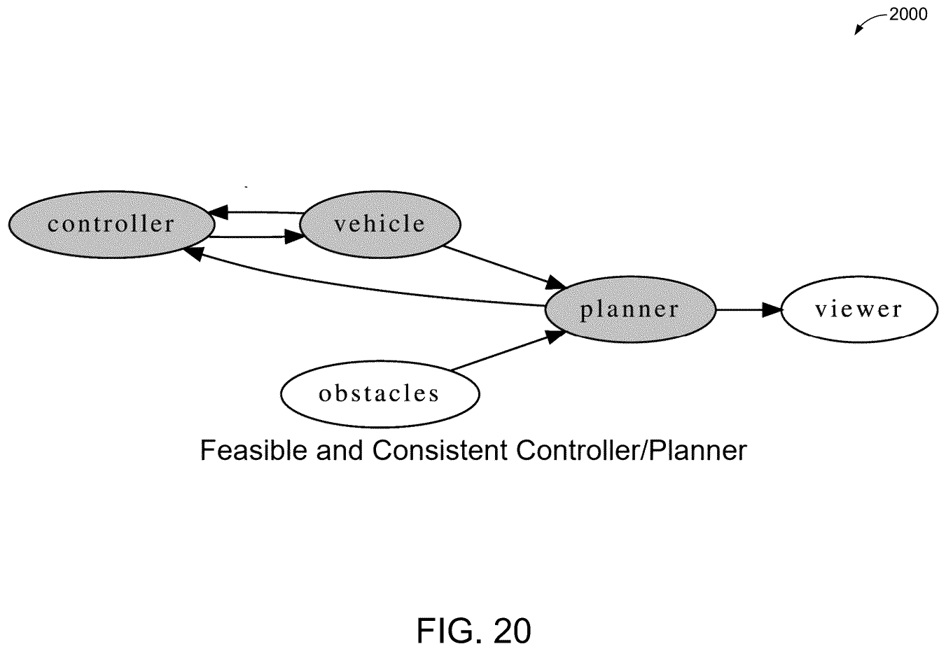

For example, the automatic subsystem selection system determines the strongly connected components of a graph using Kosaraju-Sharir's algorithm. Next, the automatic subsystem selection system may determine the reachable set of tasks from the SUT via a variation of depth-first search. The automatic subsystem selection system may determine the inverse reachable set of the SUT in two steps: first determining the transpose graph and second determining the reachable set of the SUT in the transpose graph. This results in the intersection of the reachable and inverse reachable sets. As shown in FIG. 20, a graph 2000 illustrates the collision-free, consistent set of tasks associated with the controller and planner of the graph 1900 (FIG. 19).

Idealization may be loosely defined as executing multiple tasks with the assumption that each other task executing simultaneously behaves or performs perfectly (i.e., “idealized surroundings”). Generally, users prefer idealized surroundings because this allows for a focus on the SUT. It is often desired to simulate one or more modules or tasks (e.g., the planner of FIG. 20) with idealized inputs. For example, a developer or tester may desire to assume that a controller that determines a vehicle's trajectory is ideal (i.e., can track the trajectory of the vehicle perfectly).

A naive approach to this problem is to create an idealized task representing the set complement of any set of tasks. Besides feasibility, this requires authoring 2n tasks (based on n tasks originally) which quickly becomes untenable. Another naive approach is to create an idealized version of every task and run the input set of tasks together with idealized versions of all other active tasks. This may have the advantage of being tractable because only n additional tasks must be authored (assuming n original tasks). However, providing idealized versions of tasks individually is notoriously difficult if not impossible in many cases. Instead, idealizing groups of tasks may be both possible and easier.

For example, an ideal controller is a task or module that is often tedious to implement and requires changes to other tasks. An intuitive definition of an ideal controller may include a module that tracks the reference trajectory of the vehicle without error. However, this requires infinite forces (e.g., Dirac impulses and their derivatives) to track anything exactly, which is not physically feasible, so such a controller could not be used on the vehicle. Thus, computationally, impulses must be represented and means for the vehicle dynamics integrator to handle the represented impulses that are sensible. This ends up being, at best, a complex and difficult solution.

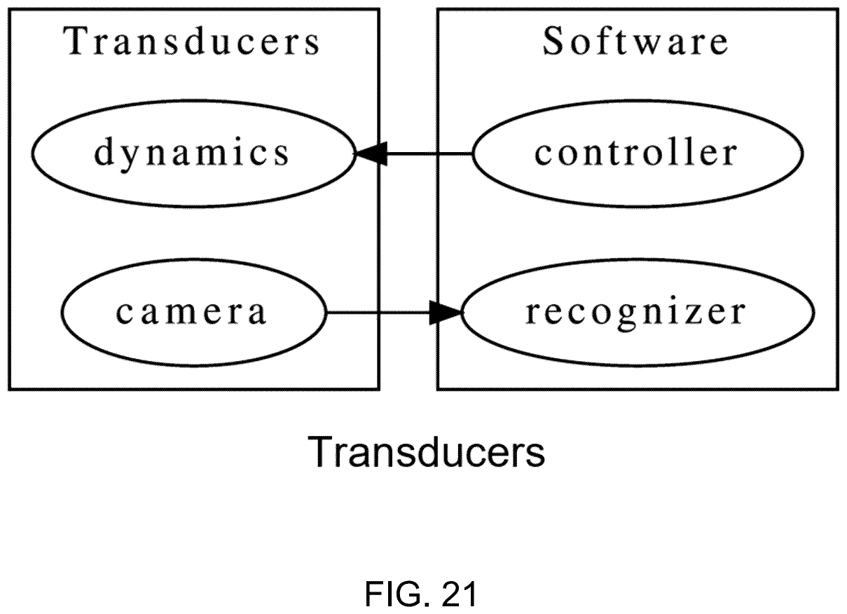

As another example, an idealized obstacle detector (or other sensing task) is practically impossible. Even with infinite computational resources (e.g., a neural network that is provably guaranteed to detect everything), vehicles would still be limited by the fact that physical cameras can only produce a finite amount of pixels per unit of angle. Transducers are the interfaces between the physical world and our software (actuators and sensors). Because ideal transducers do not exist, then it can be generalized by extension that there is no automated way to idealize the software that interfaces with them. Example transducers and the interfacing software are illustrated in FIG. 21.

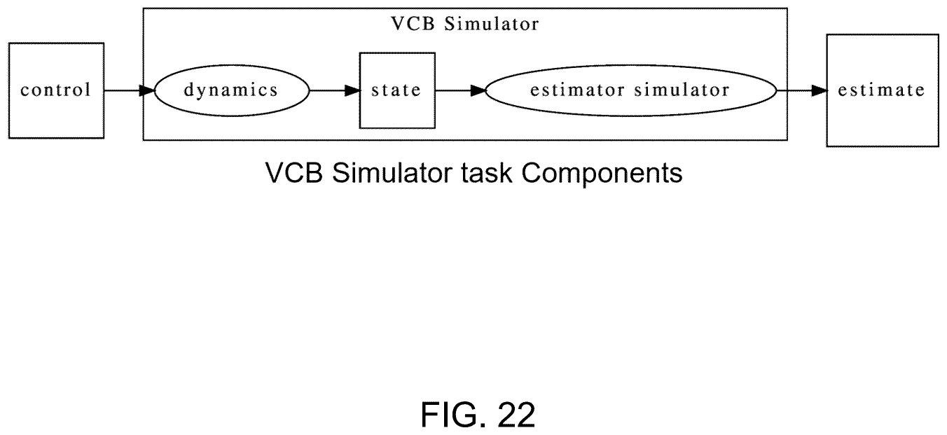

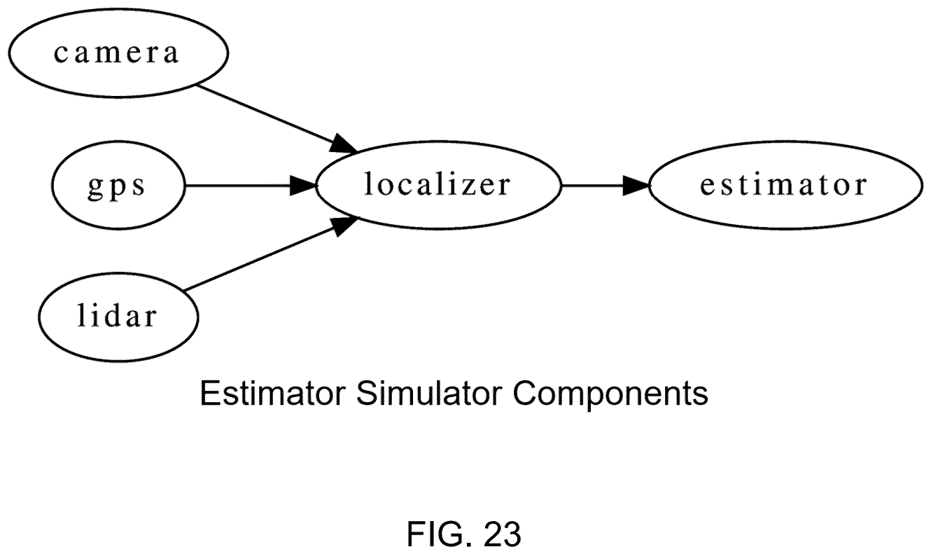

Thus, not every subset of tasks admits an idealization. Conversely, not every subset of tasks admits an idealized complement. Thus, the automatic subsystem selection system approaches this problem in a feasible and computationally solvable manner. For example, a default mode in a simulator (e.g., a task that receives vehicle commands and, based on the vehicle commands, generates the vehicle's state) may model, among other things, the entire localization pipeline, including the transducers, in an idealized way. FIG. 22 illustrates a simulator task broken into several smaller connected tasks. Here, the state block represents the ideal state, i.e., the theoretical vehicle state as computed by the dynamics simulator. The dynamics block is not idealized because, as previously discussed, an ideal dynamics block would allow the state to be controlled “perfectly”, i.e., it would behave as a see-through block that takes the state as input and generates the state unmodified. However, the estimator is an idealized bypass of several tasks (e.g., an entire perception pipeline, including hardware), some of which may not be idealizable in isolation (FIG. 23).

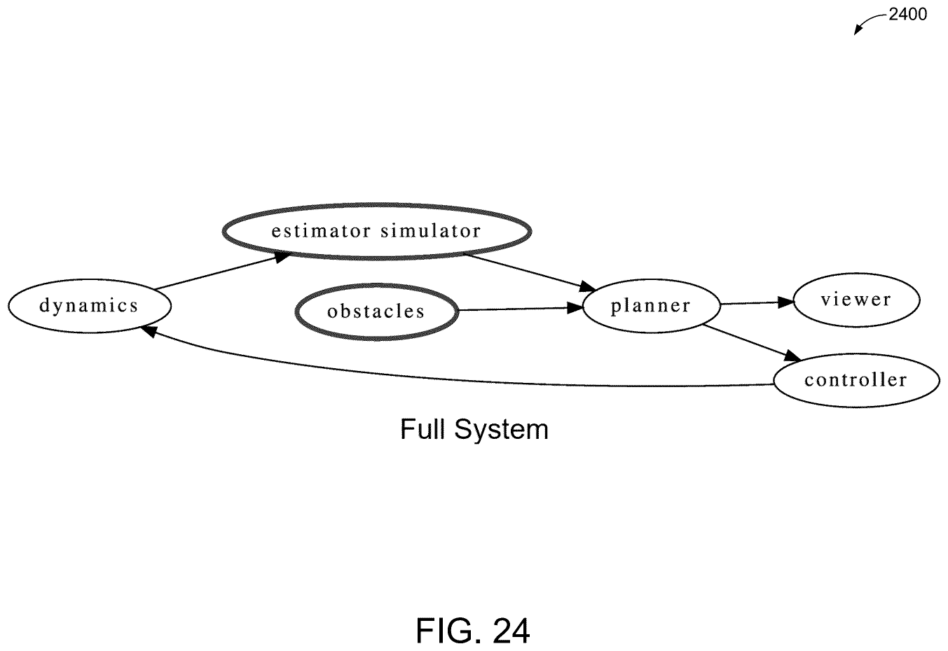

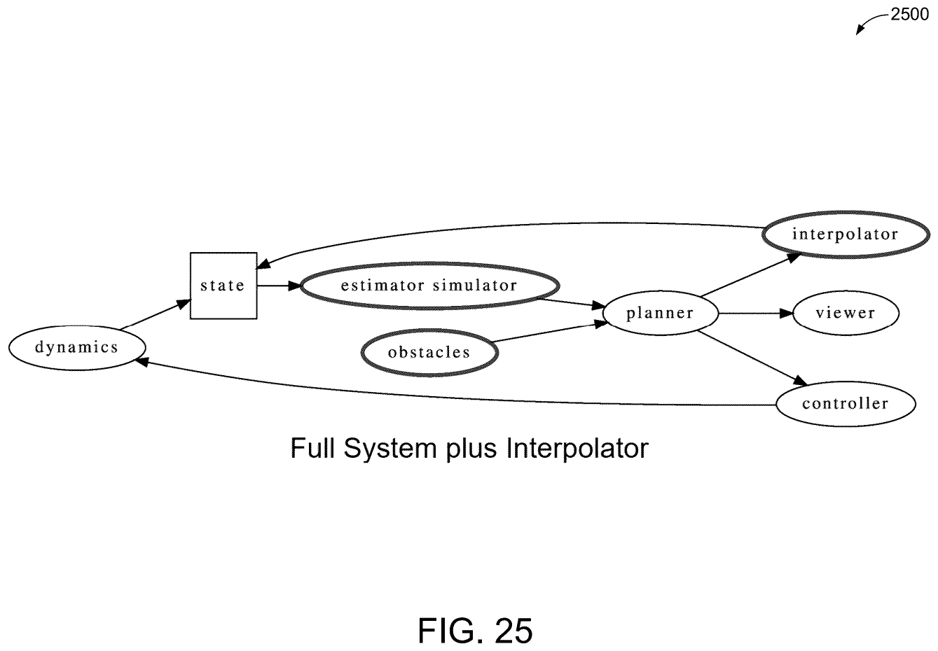

With the breakup of the simulator task, FIG. 24 illustrates another graph 2400 where the idealized blocks include the estimator simulator and the obstacles task. While the controller may be unable to be idealized by itself, the controller/dynamics pair may be idealized by bypassing the pair with a task that ideally tracks the planned route. For example, an interpolator may ideally track the planned route and insert the ideal route into the graph (i.e., the square block representing a channel that has colliding publishers). Continuing the example, FIG. 25 illustrates a graph 2500 that represents the full system with the interpolator. In this example, everything that can be idealized has been idealized. For example, a generic and/or ideal planner may not exist.

Optionally, the user invokes the automatic subsystem selection system by instructing the system to execute a module or task (e.g., a planner) with one or more options or flags, such as an instruction to idealize every module possible. The automatic subsystem selection system, based on the SUT and selected flags, options, modes, etc. selects the proper tasks or modules to execute with the SUT. That is, the automatic subsystem selection system determines a minimal, live, and collision-free set of tasks, while also maximizing the number of idealized tasks. Each of these goals may have a different associated cost (i.e., a priority). For example, maximizing the number of idealized tasks may have a lower cost or priority than ensuring tasks are live.

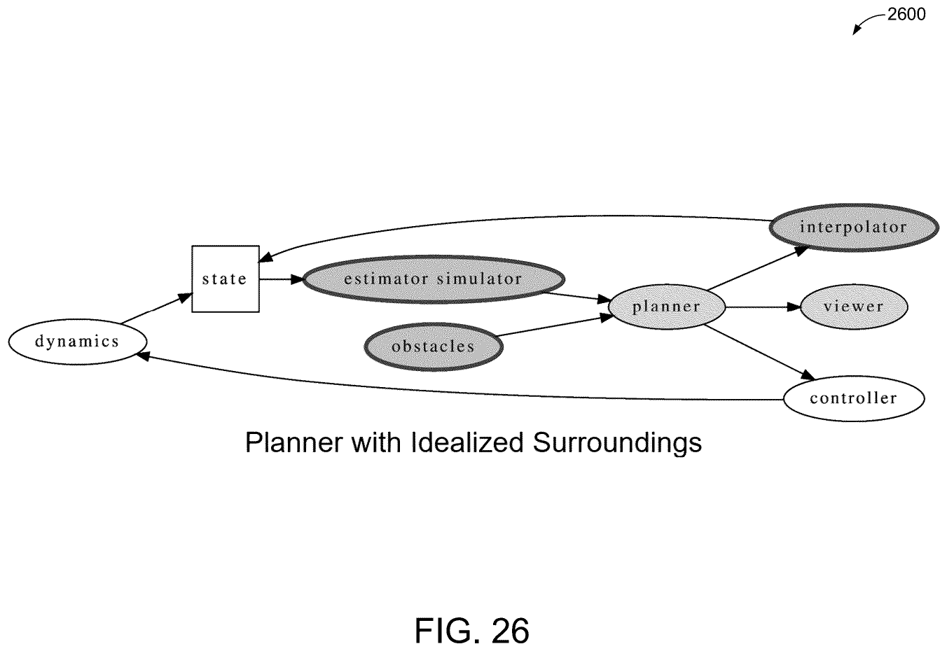

Optionally, the automatic subsystem selection system analyzes all bypassed non-idealized portions and, when they contain one of the SUT tasks, uses the non-idealized path, otherwise, uses the idealized bypass. This ensures there are no collisions while maximizing the number of idealized tasks in the search space. The automatic subsystem selection system may then apply a liveness algorithm to select a minimal set of live tasks. For example, continuing the example from FIG. 25, FIG. 26 includes an activation graph 2600 with the estimator simulator, the obstacles, the planner, the interpolator, and the viewer active as the minimal set selected for execution.

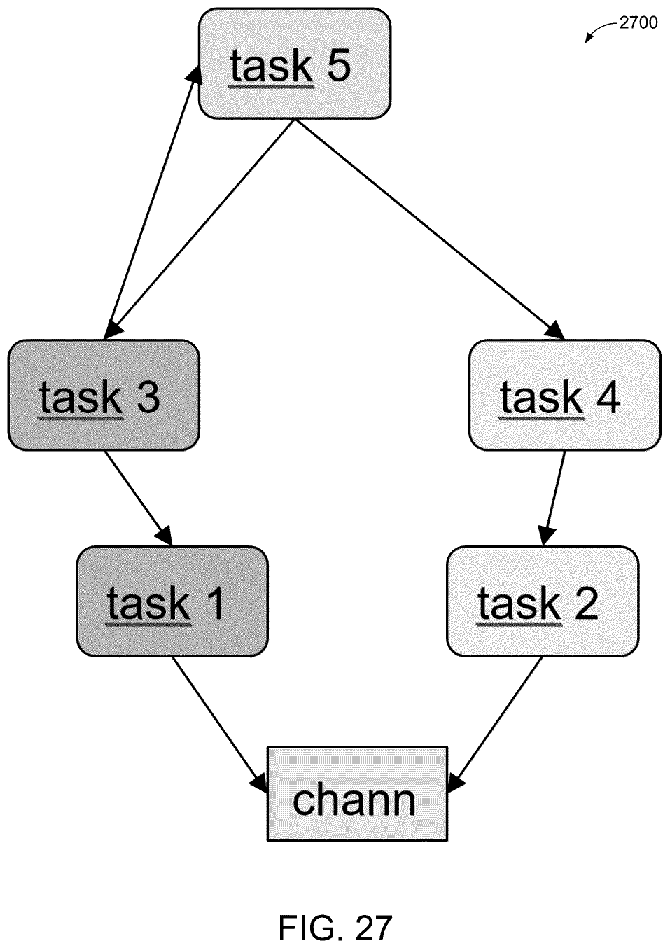

In a system that is strongly connected, there is a path between any two tasks, so independence between paths may be difficult to precisely define. FIG. 27 provides a graph where there is one “channel” that is published to by two different tasks (i.e., task 1 and task 2 both publish to the same channel). Some simple, limited scope algorithms may, with some user input, automatically select the path through task 1 and task 3 or the path through task 2 and task 4. The path here is defined as any small DAG. The automatic subsystem selection system may ensure that no task in the path may feed (i.e., provide) anything outside of the path. This is to avoid cutting off another task that needs to be fed or provided. However, the system may be allowed to stop propagating at the channel. The system may also maximize the size of the paths. This is in order to deactivate as many tasks as possible for performance. Thus, the system may perform an inverse reachability analysis starting at the tasks directly feeding the channel. The system may stop as soon as a task is encountered that feeds anything outside of what has been encountered so far. Using the example of FIG. 27, the system identifies two paths (i.e., task 1 to task 3 and task 2 to task 4), although the system may identify any number of paths. Once the system has identified the paths, the system selects one of the paths. The system may employ several disambiguation criteria. For example, the system may select the path with the most (or least) “idealized” tasks. This is a counting step provided all tasks are flagged as “idealized” or “non-idealized.” Alternatively, based on the options set by the test file or other input commands, the system may select a path with the most (or least) “non-idealized” tasks. The system may employ a “tie breaker” based on the cost or priorities of the constraints, such as selecting the path with the smallest number of tasks and/or selecting the path with the fastest execution or selecting the path with the lowest cost (where the cost weights the different factors according to the current use case).

The system may provide an interface (e.g., a graphical user interface) for the user to interact with the automatic subsystem selection system. For example, the interface pay request a number of parameters, such as the SUT parameter (e.g., a string specifying which module(s) are the SUT), an idealization parameter (e.g., a Boolean specifying whether to maximize idealization around the SUT), a dataset parameter (e.g., a string indicating which playback, if any, should be used), and/or a consistent parameter (e.g., a Boolean specifying a consistent task set for playback only). The system may provide more than one interface. For example, an advanced interface, including the parameters above, and a simple interface that instead just simulates predetermined or default modules and states based on a selected mode.

Thus, the automatic subsystem selection system helps automate the upkeep and maintenance of codebases. For example, when certain things change (e.g., new tasks, new messages, new edges), the active subsets may require change. Conventionally this includes a significant amount of time manually tweaking hard coded task sets. Testers and developers also need to fix bugs and issues with collisions/liveness/consistency. The automatic subsystem selection system handles each of these tasks. For example, the automatic subsystem selection system receives a graph (i.e., network) of tasks that communicate with each other. The graph's nodes are tasks, and there can be at most one edge between any two nodes representing all the channels that the two tasks communicate through. The graph may contain colliding tasks, i.e., tasks that publish to the same channel that should not be run at the same time. The system determines which tasks behave in an idealized fashion and which do not. The idealized tasks often “bypass” multiple realistic tasks.

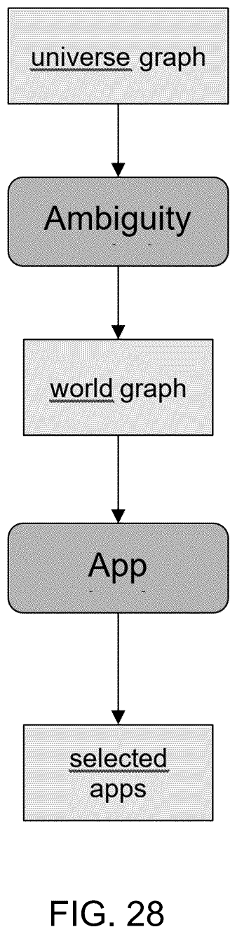

Referring now to FIG. 28, optionally, the system may receive a “universe” graph containing conflicting (i.e., publishing to the same channels) tasks, where some tasks are idealized and some tasks not. The system may perform ambiguity resolution and generate a “world” graph devoid of any conflicts. The system may next perform task/channel selection by analyzing the world graph to extract one or more tasks to execute and channels to play.

The system includes an image processor operable to process image data captured by one or more cameras, such as for detecting objects or other vehicles or pedestrians or the like in the field of view of one or more of the cameras. For example, the image processor may comprise an image processing chip selected from the EYEQ family of image processing chips available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The vehicle may include any type of sensor or sensors, such as imaging sensors or radar sensors or lidar sensors or ultrasonic sensors or the like. The imaging sensor or camera may capture image data for image processing and may comprise any suitable camera or sensing device, such as, for example, a two dimensional array of a plurality of photosensor elements arranged in at least 640 columns and 480 rows (at least a 640×480 imaging array, such as a megapixel imaging array or the like), with a respective lens focusing images onto respective portions of the array. The photosensor array may comprise a plurality of photosensor elements arranged in a photosensor array having rows and columns. The imaging array may comprise a CMOS imaging array having at least 300,000 photosensor elements or pixels, preferably at least 500,000 photosensor elements or pixels and more preferably at least one million photosensor elements or pixels or at least three million photosensor elements or pixels or at least five million photosensor elements or pixels arranged in rows and columns. The imaging array may capture color image data, such as via spectral filtering at the array, such as via an RGB (red, green and blue) filter or via a red/red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the system and/or processing and/or camera and/or circuitry may utilize aspects described in U.S. Pat. Nos. 9,233,641; 9,146,898; 9,174,574; 9,090,234; 9,077,098; 8,818,042; 8,886,401; 9,077,962; 9,068,390; 9,140,789; 9,092,986; 9,205,776; 8,917,169; 8,694,224; 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, and/or U.S. Publication Nos. US-2014-0340510; US-2014-0313339; US-2014-0347486; US-2014-0320658; US-2014-0336876; US-2014-0307095; US-2014-0327774; US-2014-0327772; US-2014-0320636; US-2014-0293057; US-2014-0309884; US-2014-0226012; US-2014-0293042; US-2014-0218535; US-2014-0218535; US-2014-0247354; US-2014-0247355; US-2014-0247352; US-2014-0232869; US-2014-0211009; US-2014-0160276; US-2014-0168437; US-2014-0168415; US-2014-0160291; US-2014-0152825; US-2014-0139676; US-2014-0138140; US-2014-0104426; US-2014-0098229; US-2014-0085472; US-2014-0067206; US-2014-0049646; US-2014-0052340; US-2014-0025240; US-2014-0028852; US-2014-005907; US-2013-0314503; US-2013-0298866; US-2013-0222593; US-2013-0300869; US-2013-0278769; US-2013-0258077; US-2013-0258077; US-2013-0242099; US-2013-0215271; US-2013-0141578 and/or US-2013-0002873, which are all hereby incorporated herein by reference in their entireties. The system may communicate with other communication systems via any suitable means, such as by utilizing aspects of the systems described in U.S. Pat. Nos. 10,071,687; 9,900,490; 9,126,525 and/or 9,036,026, which are hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A method for testing a vehicular control system, the method comprising:
receiving, at a simulator, data comprising a plurality of tasks and a plurality of channels, wherein respective tasks of the plurality of tasks communicate via respective channels of the plurality of channels;
receiving, at the simulator, and from a user device, a system under test (SUT) selection selecting one of the plurality of tasks for testing;
determining, using the data and the SUT selection, an inverse reachability set of tasks from the plurality of tasks, wherein the inverse reachability set of tasks comprises a subset of the plurality of tasks to provide the SUT selection live data during simulation, and wherein the inverse reachability set of tasks does not include at least one task from the plurality of tasks; and
simulating, by the simulator, only the tasks of the inverse reachability set of tasks to test the SUT selection.

2. The method of claim 1, wherein the data comprises a directed graph.

3. The method of claim 2, wherein determining the inverse reachability set of tasks from the plurality of tasks comprises determining a transpose graph of the directed graph.

4. The method of claim 1, wherein determining the inverse reachability set of tasks from the plurality of tasks comprises:
performing a single depth-first search; and
determining, from the single depth-first search, that each vertex that is reachable from each task in the data.

5. The method of claim 1, wherein receiving the SUT selection comprises receiving a test file that comprises the SUT selection.

6. The method of claim 5, wherein the test file further comprises at least one selection parameter, and wherein the at least one selection parameter comprises at least one selected from the group consisting of (i) an idealization parameter instructing the simulator to idealize one or more tasks, (ii) a playback parameter indicating to the simulator which tasks have playback available and (iii) a freshness parameter instructing the simulator to replace recorded messages with fresh messages.

7. The method of claim 6, wherein the idealization parameter comprises a Boolean value.

8. The method of claim 6, wherein the freshness parameter comprises a Boolean value.

9. The method of claim 1, further comprising determining that the inverse reachability set of tasks is collision-free.

10. The method of claim 9, wherein determining that the inverse reachability set of tasks is collision-free comprises:
determining one or more strongly connected components of the data;
determining, using the one or more strongly connected components, a reachable set of the plurality of tasks for the SUT selection; and
determining, using the reachable set of the plurality of tasks for the SUT selection, the inverse reachability set of tasks for the SUT selection.

11. The method of claim 1, further comprising, prior to simulating only the tasks of the inverse reachability set of tasks:
determining an idealized task for one of the tasks of the inverse reachability set of tasks is available; and
substituting the idealized task for the one of the tasks in the inverse reachability set of tasks.

12. The method of claim 1, wherein the data comprises a graph, and wherein the graph is generated from configuration files of the plurality of tasks.

13. The method of claim 12, wherein the configuration files comprise JavaScript Object Notation (JSON) files.

14. The method of claim 1, wherein the data is generated from logging channel subscriptions by each task during simulation of each of the plurality of tasks.

15. The method of claim 1, wherein the inverse reachability set comprises a minimal set of live tasks to test the SUT selection.

16. The method of claim 1, wherein the inverse reachability set of tasks comprises a liveness preserving set (LPS).

17. A method for testing a vehicular control system, the method comprising:
receiving, at a simulator, a directed graph comprising a plurality of tasks and a plurality of channels, wherein respective tasks of the plurality of tasks communicate via respective channels of the plurality of channels;
receiving, at the simulator, and from a user device, a system under test (SUT) selection selecting one of the plurality of tasks for testing;
receiving, at the simulator, at least one selection parameter comprising at least one selected from the group consisting of (i) an idealization parameter instructing the simulator to idealize one or more tasks, (ii) a playback parameter indicating to the simulator which tasks have playback available and (iii) a freshness parameter instructing the simulator to replace recorded messages with fresh messages;
determining, using the directed graph, the SUT selection and the at least one selection parameter, an inverse reachability set of tasks from the plurality of tasks, wherein the inverse reachability set of tasks comprises a subset of the plurality of tasks to provide the SUT selection live data during simulation, and wherein the inverse reachability set of tasks does not include at least one task from the plurality of tasks; and
simulating, by the simulator, only the tasks of the inverse reachability set of tasks to test the SUT selection.

18. The method of claim 17, wherein the idealization parameter comprises a Boolean value.

19. The method of claim 17, wherein the freshness parameter comprises a Boolean value.

20. The method of claim 17, wherein determining the inverse reachability set of tasks from the plurality of tasks comprises determining a transpose graph of the directed graph.

21. A method for testing a vehicular control system, the method comprising:
receiving, at a simulator, data comprising a plurality of tasks and a plurality of channels, wherein respective tasks of the plurality of tasks communicate via respective channels of the plurality of channels;
receiving, at the simulator, and from a user device, a system under test (SUT) selection selecting one of the plurality of tasks for testing;
determining, using the data and the SUT selection, an inverse reachability set of tasks from the plurality of tasks, wherein the inverse reachability set of tasks comprises a subset of the plurality of tasks to provide the SUT selection live data during simulation, and wherein the inverse reachability set of tasks does not include at least one task from the plurality of tasks;
determining that the inverse reachability set of tasks is collision-free;
determining an idealized task for one of the tasks of the inverse reachability set of tasks is available;
substituting the idealized task for the one of the tasks in the inverse reachability set of tasks; and
simulating, by the simulator, only the tasks of the inverse reachability set of tasks to test the SUT selection.

22. The method of claim 21, wherein the data comprises a graph, and wherein the graph is generated from configuration files of the plurality of tasks.

23. The method of claim 22, wherein the configuration files comprise JavaScript Object Notation (JSON) files.

24. The method of claim 21, wherein the data is generated from logging channel subscriptions by each task during simulation of each of the plurality of tasks.
